(19) United States
(12) Patent Application Publication
(10) Pub. No.: US 2008/0067600 A1
(43) Pub. Date: Mar. 20, 2008

(54) Storage Elements with Disguised Configurations and Methods of Using the Same

(76) Inventors: Louis Lu-Chen Hsu, Fishkill, NY (US); Jack A. Mandelman, Flat Rock, NC (US); William R. Tonti, Essex Junction, VT (US); Chih-Chao Yang, Poughkeepsie, NY (US)

Correspondence Address: IBM Corporation;Intellectual Property Law Dept. 917, 3605 Hwy. 52 North, Rochester, MN, 55901, US

(21) Appl. No.: 11/533,191

(22) Filed: Sep. 19, 2006

(51) Int. Cl. H01L 23/62

(52) U.S. Cl. 257/360

(57) ABSTRACT

In a first aspect, a first apparatus is provided. The first apparatus is an element of an integrated circuit (IC) having (1) a metal-oxide-semiconductor field-effect transistor (MOSFET) having source/drain diffusion regions; (2) an electrical fuse (eFuse) coupled to the MOSFET such that a portion of the eFuse serves as a gate region of the MOSFET; and (3) an implanted region coupled to the source/drain diffusion regions of the MOSFET such that a path between the source/drain diffusion regions functions as a short circuit or an open circuit. Numerous other aspects are provided.

### FIELD OF THE INVENTION

The present invention relates generally to integrated circuits, and more particularly to storage elements with disguised configurations and methods of using the same.

### BACKGROUND

A conventional integrated circuit (IC) may include at least one programmable circuit element, such as an on-chip electrical fuse (eFuse) or antifuse, which is employed to customize the IC. For example, based on the programmed state of an eFuse, features of the IC may be enabled or disabled according to a contracted or authorized need of a customer.

The programmed state of an eFuse included in an IC may be easily detected. Consequently, the IC may be easily reverse engineered. Such an easily reverse-engineered IC is not desirable if the IC is employed for aerospace, military, defense, financial or any other systems impacting national security. Consequently, a programmable circuit element of an IC that prevents reverse engineering of the IC is desired.

### SUMMARY OF THE INVENTION

In a first aspect of the invention, a first apparatus is provided. The first apparatus is an element of an integrated circuit (IC) having (1) a metal-oxide-semiconductor field-effect transistor (MOSFET) having source/drain diffusion regions; (2) an electrical fuse (eFuse) coupled to the MOSFET such that a portion of the eFuse serves as a gate region of the MOSFET; and (3) an implanted region coupled to the source/drain diffusion regions of the MOSFET such that a path between the source/drain diffusion regions functions as a short circuit or an open circuit.

In a second aspect of the invention, a first system is provided. The first system is an integrated circuit (IC) that includes (1) a substrate; and (2) an element formed on the substrate. The element includes (a) a metal-oxide-semiconductor field-effect transistor (MOSFET) having source/drain diffusion regions; (b) an electrical fuse (eFuse) coupled to the MOSFET such that a portion of the eFuse serves as a gate region of the MOSFET; and (c) an implanted region coupled to the source/drain diffusion regions of the MOSFET such that a path between the source/drain diffusion regions functions as a short circuit or an open circuit.

In a third aspect of the invention, a first method is provided. The first method includes the steps of (1) providing an element of an integrated circuit (IC) having (a) a metal-oxide-semiconductor field-effect transistor (MOSFET) having source/drain diffusion regions; (b) an electrical fuse (eFuse) coupled to the MOSFET such that a portion of the eFuse serves as a gate region of the MOSFET; and (c) an implanted region coupled to the source/drain diffusion regions of the MOSFET such that a path between the source/drain diffusion regions functions as a short circuit or an open circuit; and (2) employing the element to provide a current gain independent of a programmed state of the eFuse. Numerous other aspects are provided, as are systems and apparatus in accordance with these and other aspects of the invention.

Other features and aspects of the present invention will become more fully apparent from the following detailed description, the appended claims and the accompanying drawings.

### BRIEF DESCRIPTION OF THE FIGURES

FIG. 1 illustrates a first exemplary element of an IC, which includes an eFuse coupled to a MOSFET, in an unprogrammed state in accordance with an embodiment of the present invention.

FIG. 2 illustrates the element of FIG. 1 in a programmed state in accordance with an embodiment of the present invention.

FIG. 3 illustrates an implanted region that may be included in the element of FIGS. 1 and 2 in accordance with an embodiment of the present invention.

FIG. 4 is a graph illustrating a relationship between a voltage applied to a cathode of the element and a current gain provided by the element in accordance with an embodiment of the present invention.

FIG. 5 illustrates a second exemplary IC element which includes an eFuse coupled to a MOSFET in accordance with an embodiment of the present invention.

FIG. 6 illustrates a third exemplary IC element which includes an eFuse coupled to a MOSFET in accordance with an embodiment of the present invention.

FIG. 7 illustrates a fourth exemplary IC element which includes an eFuse coupled to a MOSFET in accordance with an embodiment of the present invention.

FIG. 8 illustrates a fifth exemplary IC element which includes an eFuse coupled to a MOSFET in accordance with an embodiment of the present invention.

FIG. 9 illustrates a sixth exemplary IC element which includes an eFuse coupled to a MOSFET in accordance with an embodiment of the present invention.

FIG. 10 illustrates a seventh exemplary IC element which includes an eFuse coupled to a MOSFET in accordance with an embodiment of the present invention.

FIG. 11 illustrates an eighth exemplary IC element which includes an eFuse coupled to a MOSFET in accordance with an embodiment of the present invention.

FIG. 12 illustrates a ninth exemplary IC element which includes an eFuse coupled to a MOSFET in accordance with an embodiment of the present invention.

FIG. 13 illustrates a tenth exemplary IC element which includes an eFuse coupled to a MOSFET in accordance with an embodiment of the present invention.

FIG. 14 illustrates an eleventh exemplary IC element which includes an eFuse coupled to a MOSFET in accordance with an embodiment of the present invention.

FIG. 15 illustrates a twelfth exemplary IC element which includes an eFuse coupled to a MOSFET in accordance with an embodiment of the present invention.

FIG. 16 illustrates a thirteenth exemplary IC element which includes an eFuse coupled to a MOSFET in accordance with an embodiment of the present invention.

FIG. 17 illustrates a fourteenth exemplary IC element which includes an eFuse coupled to a MOSFET in accordance with an embodiment of the present invention.

FIG. 18 illustrates a fifteenth exemplary IC element which includes an eFuse coupled to a MOSFET in accordance with an embodiment of the present invention.

### DETAILED DESCRIPTION

The present invention provides methods and apparatus for preventing reverse engineering of an IC. More specifically, the present invention provides a programmable circuit element of an IC that prevents reverse engineering of the IC. The circuit element may be a gain storage element including a metal-oxide-semiconductor field-effect transistor (MOSFET) coupled to an eFuse such that a portion of the eFuse may be coupled to or serve as a gate region of the MOSFET. An eFuse is a known polysilicon conductor clad with a refractory metal that is used to aid in heating the eFuse and alter its native low resistance state to a high resistance state.

Without additional circuit elements as discussed in this specification, a programmed state of the eFuse would control operation of this inventive MOSFET (e.g., control the current gain Igain of the MOSFET). However, the gain storage element of the present invention additionally may include an implanted region which couples source/drain diffusion regions of the MOSFET such that the MOSFET exhibits a fixed current gain (otherwise known as the eFuse program state) regardless of the programmed state of the eFuse coupled thereto. More specifically, the current gain may be pinned to one state independent of its gate state programming because a current gain sense path may not be dependent on a state of the conductive polysilicon. This is a sufficient condition in disguising the state of the eFuse.

Because the implanted region may be hidden by overlying layers of the eFuse and/or MOSFET and may be located in various locations of the gain storage element, the implanted region is difficult to detect. Consequently, although the programmed state of the eFuse may be easily detected (e.g., optically or by scanning electron microscopy) such programmed state may not actually indicate which features of the IC are enabled and which features of the IC are disabled. Therefore, the programmed state of the eFuse of the gain storage element may serve as a decoy by disguising enabled and/or disabled features of an IC, thereby preventing reverse engineering.

For example, assuming the MOSFET of the gain storage element is an n-channel MOSFET (NFET), the implant may serve to create a short circuit between the source/drain diffusion regions of the MOSFET, which causes the MOSFET to provide a high Igain regardless of the programmed state of the eFuse included in the gain storage element. Alternatively, the implant may serve to create an open circuit between the source/drain diffusion regions of the MOSFET, which causes the MOSFET to provide a low Igain regardless of the programmed state of the eFuse included in the gain storage element. In this manner, the present invention provides methods and apparatus for preventing reverse engineering of an IC.

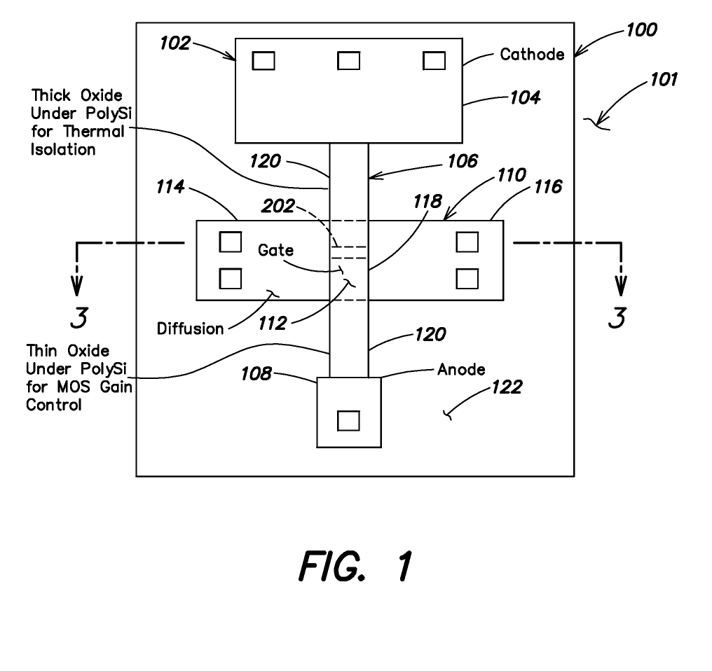

FIGS. 1-18 relate to fifteen different exemplary IC gain storage elements, each of which includes an eFuse coupled to a MOSFET such that a portion (e.g., a cathode) of the eFuse may serve as a gate region of the MOSFET. Each exemplary IC gain storage element (e.g., an n-channel MOSFET included therein) may be adapted to provide a first current gain Igain1 when the eFuse is in a first programmed state (e.g., programmed) and a second current gain Igain2 when the eFuse is in a second programmed state (e.g., unprogrammed). Igain1 may be independent of an electromigration length of the programmed eFuse. The difference (e.g., delta) between Igain2 and Igain1 may be eight orders of magnitude, taking advantage of the known MOSFET switching characteristic. Consequently, a chance of the current gain provided by the element being incorrectly sensed (e.g., read) is much improved over the present state of the art. The present state of the art detects a relatively small change in resistance of the programmed element.

Some of the exemplary IC gain storage elements may not be radiation hardened, and therefore, may be susceptible to damage caused radiation (e.g., a total ionizing dose). However, such exemplary IC gain storage elements may be useful in many applications (e.g., non-military, non-defense or non-aerospace applications). Some of such non-radiation hardened gain storage element designs may be adapted to provide thermal isolation.

Alternatively, some of the exemplary IC gain storage elements may be radiation hardened, and therefore, resistant to damage caused by radiation. Some of such radiation-hardened gain storage element designs may be adapted to provide thermal isolation.

Non-Radiation-Hardened Gain Storage Element Designs

FIG. 1 illustrates a first exemplary element 100 of an IC 101, which includes an eFuse coupled to a MOSFET, in an unprogrammed state in accordance with an embodiment of the present invention. With reference to FIG. 1, the first exemplary element 100 may include an eFuse 102 having a cathode 104 coupled via a polysilicon region 106 to an anode 108. The eFuse 102 may be programmed by driving a current through the polysilicon region 106. The element 100 may include a MOSFET 110 (e.g., an n-channel MOSFET (NFET) or a p-channel MOSFET (PFET)), which includes a gate region 112 coupled between first and second source/drain diffusion regions 114, 116, coupled to the eFuse 102. More specifically, one or more portions 118 of the polysilicon region 106 may be coupled to and/or comprise the gate region 112 (e.g., gate electrode) of the MOSFET 110. A thin oxide layer (obstructed by the polysilicon region 106) may be beneath the one or more portions 118 of the polysilicon region 106 coupled to the gate region 112. Such thin oxide layer may provide MOSFET control, and ultimately the eFuse gain control. A thick oxide layer (obstructed by the polysilicon region 106) may be beneath remaining portions 120 of the polysilicon region 106. Such thick oxide layer may provide thermal isolation (e.g., from remaining elements of the IC 100). A shallow-trench isolation (STI) oxide region 122 may be formed adjacent the eFuse 102 and the MOSFET 110.

A gain (e.g., current gain) provided by the MOSFET 110 may be sensed from the source/drain diffusion regions 114, 116. Thus, a path employed to program the element 100 may be separated from a path employed to sense a gain provided by the element 100.

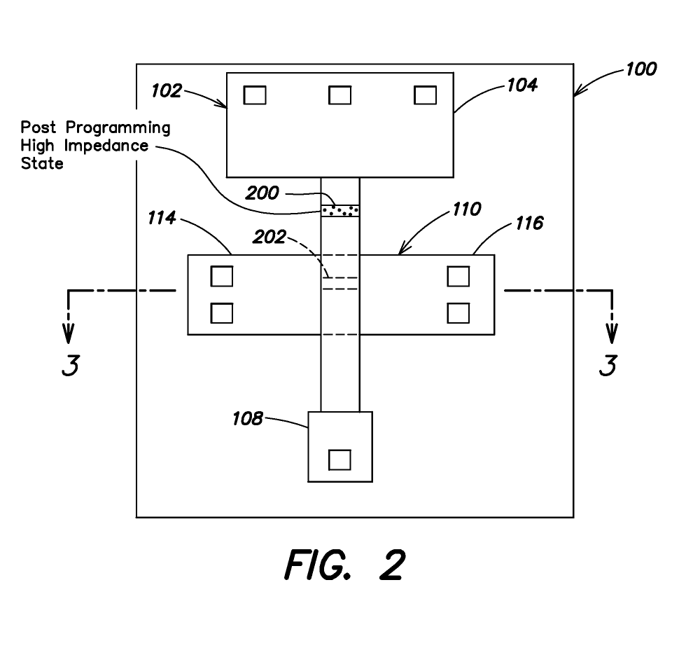

Because the eFuse 102 (in this example an n-channel gain eFuse) is in the unprogrammed state, the MOSFET 110 may provide the second current gain Igain2. Alternatively, if the eFuse 102 is in a programmed state, the MOSFET 110 may provide the first current gain Igain1. FIG. 2 illustrates the element 100 of FIG. 1 in a programmed state in accordance with an embodiment of the present invention. With reference to FIG. 2, in the programmed state, the eFuse 102 may include a high-impedance region 200 (e.g., proximate the cathode 104). The high-impedance region 200 may be formed by independently driving a substantial current between the cathode 104 and anode 108 of the eFuse 102. Such a physical change (e.g., formation of the high-impedance region 200) in the polysilicon region 106 may result in a substantial increase in resistance of the gate electrode, which causes the MOSFET 110 to provide the first current gain Igain1.

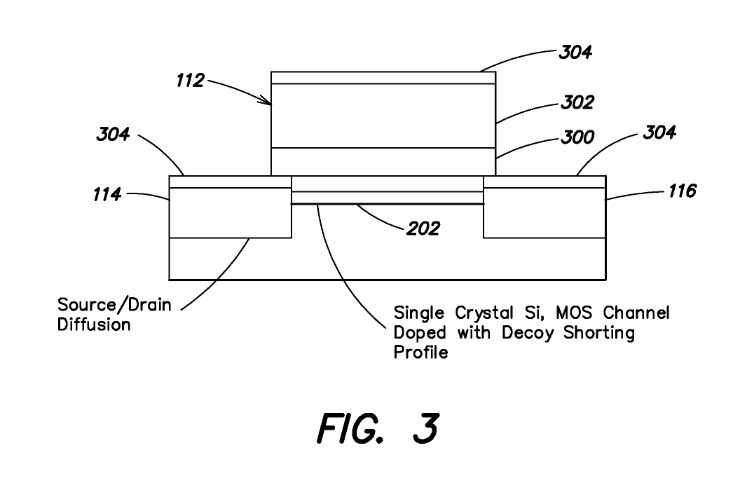

Additionally, the physical change may easily be detected (e.g., via physical inspection), and therefore, a configuration of such a circuit may be easily reverse engineered. Consequently, in some embodiments, the first exemplary element 100 of the IC 101 may include a structure or element adapted to disguise or mask the actual IC configuration, thereby preventing reverse engineering of the IC 101. More specifically, in some embodiments, the first exemplary element 100 of FIGS. 1 and 2 may include an implanted region 202 (shown in phantom) coupled to the source/drain diffusion regions 114, 116 of the MOSFET 110 such that a path between the source/drain diffusion regions 114, 116 functions as a short circuit or an open circuit. The implanted region 202 may be a buried connection, and therefore, may not be easily detected. As shown, the implanted region 202 is a short circuit across and under the polysilicon conductor 106. FIG. 3 is a cross-sectional side view of the first exemplary element 100 of FIGS. 1 and 2 taken along line 3-3 in accordance with an embodiment of the present invention. With reference to FIG. 3, the implanted region 202, which couples and short circuits the source/drain diffusion regions 114, 116 of the MOSFET 110 may be below one or more portions of the gate region 112 of the MOSFET 110 (e.g., in a channel region of the MOSFET 110). The gate region 112 may include a thin oxide layer 300, which is below a polysilicon layer 302 which is below a silicide layer 304 (e.g., a material layer comprising Tungsten Silicide (WSi), Cobalt Disilicide (CoSi2), Platinum Silicide (PtSi), Nickel Silicide (NiSi) and/or the like). The silicide layer 304 may also be formed on the source/drain diffusion regions 114, 116. For convenience, the silicide layer 304 is not shown in FIGS. 1 and 2. The polysilicon layer 302 (e.g., a uniformly-doped polysilicon layer) may comprise a portion of the polysilicon region 106 of the eFuse 102.

The implanted region 202 may cause the element 100 to provide a fixed current gain (e.g., either Igain1 or Igain2), which is independent of the programmed state of the eFuse 102. For example, assuming the MOSFET 110 is an NFET, the implanted region 202 may include a concentration of about 4×10¹⁷ to about 1×10¹⁸ ions/cm³ of an n-type dopant (e.g., phosphorous, arsenic and/or the like). However, a larger or smaller and/or different concentration range may be employed. Such a dopant may have the same polarity as the source/drain diffusion regions 114, 116. The implanted region 202 may serve to create a short circuit between the source/drain diffusion regions 114, 116. Consequently, such an implanted region 202 may cause the MOSFET 110 to provide a fixed or “stuck-at” current gain (e.g., the second current gain Igain2) regardless of the programmed state, which may affect a voltage applied to the gate region 112, of the eFuse 102. Because such an implanted region 202 is employed to short the source/drain diffusion regions 114, 116, the implanted region 202 may occupy one or more portions of the area below the gate region 112. To wit, the implanted region 202 is not required to occupy the entire area below the gate region 112. Consequently, such an implanted region 202 may be formed in a variety of locations, and easily hidden.

Alternatively, the implanted region 202 may include a concentration of greater than about 1×10¹⁸ ions/cm³ of a p-type dopant (e.g., boron, boron difluoride (BF₂) and/or the like) However, a larger or smaller and/or different concentration range may be employed. Such an implanted region 202 may serve as a high threshold voltage (Vt) implant, which may cause the Vt of the MOSFET 112 to exceed a power supply voltage. Such an implanted region 202 may serve to create an open circuit between the source/drain diffusion regions 114, 116. Consequently, such an implanted region 202 may cause the MOSFET 110 to provide a fixed or “stuck-at” current gain (e.g., the first current gain Igain1) regardless of the programmed state of the eFuse 102. Because such an implanted region 202 is employed to form an open circuit between the source/drain diffusion regions 114, 116, the implanted region 202 should occupy one or more portions of the area below the gate region 112 such that all paths between the source/drain diffusion regions 114, 116 travel through the implanted region 202.

Duality exists when the MOSFET 110 is a PFET. For example, assuming the MOSFET 110 is a PFET, the implanted region 202 may include a concentration of about 4×10¹⁷ to about 1×10¹⁸ ions/cm³ of a p-type dopant (e.g., boron, boron difluoride (BF₂) and/or the like). However, a larger or smaller and/or different concentration range may be employed. Such a dopant may have the same polarity as the source/drain diffusion regions 114, 116. The implanted region 202 may serve to create a short circuit between the source/drain diffusion regions 114, 116. Consequently, such an implanted region 202 may cause the MOSFET 110 to provide a fixed or “stuck-at” current gain (e.g., the second current gain |Igain2|) regardless of the programmed state, which may affect a voltage applied to the gate region 112, of the eFuse 102. Because such an implanted region 202 is employed to short the source/drain diffusion regions 114, 116, the implanted region 202 may occupy the entire area below the gate region 112. To wit, the implanted region 202 is not required to occupy the entire area below the gate region 112. Consequently, such an implanted region 202 may be formed in a variety of locations.

Alternatively, the implanted region 202 may include a concentration of greater than about 1×10¹⁸ ions/cm³ of an n-type dopant (e.g., phosphorous, arsenic and/or the like). However, a larger or smaller and/or different concentration range may be employed. Such an implanted region 202 may serve as a high threshold voltage (Vt) implant, which may cause the Vt of the MOSFET 112 to exceed a power supply voltage. The implanted region 202 may serve to create an open circuit between the source/drain diffusion regions 114, 116. Consequently, such an implanted region 202 may cause the MOSFET 110 to provide a fixed or “stuck-at” current gain (e.g., the first current gain, Igain1) regardless of the programmed state of the eFuse 102. Because such an implanted region 202 is employed to form an open circuit between the source/drain diffusion regions 114, 116, the implanted region 202 should occupy one or more portions of the area below the gate region 112 such that all paths between the source/drain diffusion regions 114, 116 travel through the implanted region 202.

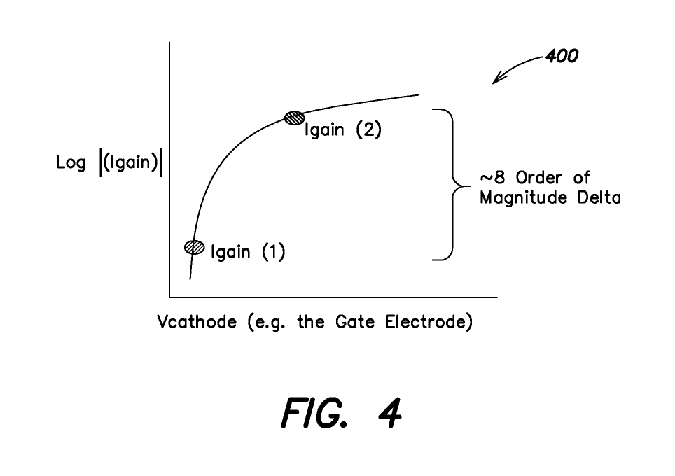

FIG. 4 is a graph 400 illustrating a relationship between a voltage V_{cathode} applied to a cathode 104 of the element 100 and a current gain Igain provided by the element 100 in accordance with an embodiment of the present invention. With reference to FIG. 4, assuming the element 100 does not include the implanted region 202, when V_{cathode} has a first value, the MOSFET 110 (e.g., a gain cell) provides the first current gain Igain1, and when V_{cathode} has a second value (e.g., when a gate electrode is raised to a high input level via the cathode 104), the MOSFET (n-channel in this example) 110 provides the second current gain Igain2 (or vice versa). However, assuming the element 100 includes an implanted region 202 that serves to form a short circuit between the source/drain diffusion regions 114, 116, the MOSFET 110 provides a first fixed current gain, Igain1. Further, assuming the element 100 includes an implanted region 202 that serves to form an open circuit between the source/drain diffusion regions 114, 116, the MOSFET 110 provides a second fixed current gain Igain2.

An element including an implanted region 202 may appear physically identical to an element which does not include the implanted region, however the element including the implanted region 202 may not be affected by a programmed state of its eFuse 102 (portions of which serve as a gate electrode). For example, although an eFuse 102 of an element 100 including an implanted region 202 may be programmed like an element that does not include the implanted region 202, such programming may not affect the fixed current gain provided by the element 100.

As shown, the delta between Igain2 and Igain1 is about eight orders of magnitude. Consequently, a chance of the current gain provided by the element 100 being incorrectly sensed (e.g., read) is negligible.

Non-Radiation-Hardened Thermally-Isolating Designs

Thermal energy may be created when the eFuse 102 of the element 100 is programmed. The polysilicon region 106 of the eFuse 102 may be coupled to and/or serve as a portion of the gate region 112. Further, the polysilicon region 106 may be on the same level as the gate region 112. Therefore, the MOSFET 110 is in the programming path of the eFuse 102 and may adversely be affected by the thermal energy created while programming the eFuse 102.

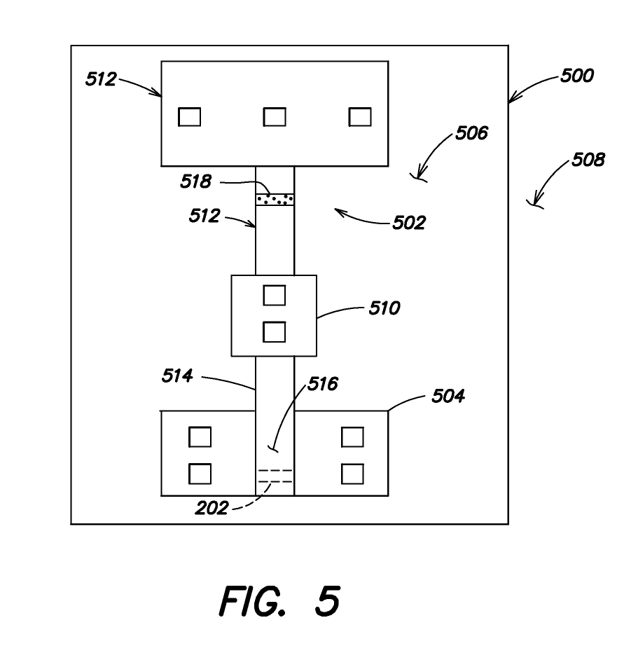

FIG. 5 illustrates a second exemplary IC element 500 which includes an eFuse 502 coupled to a MOSFET 504 in accordance with an embodiment of the present invention. With reference to FIG. 5, similar to the first exemplary element 100, the second exemplary element 500 includes an eFuse 502 coupled to a MOSFET 504. The element 500 may include an STI oxide region 506 adjacent the eFuse 502 and MOSFET 504. The second exemplary element 500 may be programmed and/or sensed similar to the first exemplary element 100. Further, in some embodiments, the second exemplary element 500 may include an implanted region 202 similar to that described above with reference to FIGS. 1-3. The programmed state of the eFuse 502 may serve as a decoy configuration. Consequently, actual configuration of an IC 508 including the element 500 may be disguised or masked. However, the second exemplary element 500 may be adapted to provide thermal protection to the MOSFET 504 while programming the eFuse 502. More specifically, an anode 510 of the eFuse 502 may be moved such that the MOSFET 504 is not in a programming path between the anode 510 and a cathode 512 of the eFuse 502. In this manner, compared to the first exemplary element 100, the programming current in the second exemplary element 500 is altered such that the current does not pass through the MOSFET 504 (e.g., an active gate region 516 of the MOSFET 504). A portion 514 of a polysilicon region 512 coupling the anode 510 and cathode 512 may also couple the anode 510 to the MOSFET 504 (e.g., to a gate region 516 thereof). Although the element 500 is shown in the programmed state (e.g., a high-impedance region 518 is formed in a polysilicon region 512 of the eFuse 502), the element 500 may also be configured in an unprogrammed state.

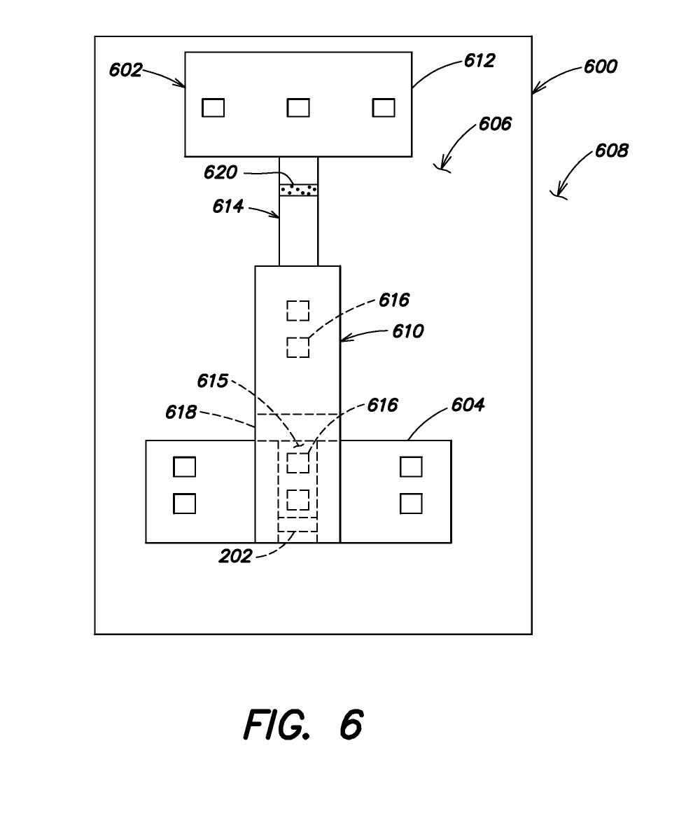

FIG. 6 illustrates a third exemplary IC element 600 which includes an eFuse 602 coupled to a MOSFET 604 in accordance with an embodiment of the present invention. With reference to FIG. 6, the third exemplary element 600 is similar to the second exemplary element 500. More specifically, the third exemplary element 600 includes an eFuse 602 coupled to a MOSFET 604. The element 600 may include an STI oxide region 606 adjacent the eFuse 602 and MOSFET 604. The third exemplary element 600 may be programmed and/or sensed similar to the second exemplary element 500. Further, in some embodiments, the third exemplary element 600 may include an implanted region 202 similar to that described above with reference to FIGS. 1-3. Consequently, configuration of an IC 608 including the element 600 may be disguised or masked.

Additionally, similar to the second exemplary element 500, the third exemplary element 600 may be adapted to provide thermal protection to the MOSFET 604 while programming the eFuse 602. More specifically, an anode 610 of the eFuse 602 may be moved such that the MOSFET 604 is not in a programming path between the anode 610 and a cathode 612 of the eFuse 602. The programming path may be defined by a polysilicon region 614 coupling the anode 610 and cathode 612. In this manner, compared to the first exemplary element 100, the programming current in the third exemplary element 600 is altered so that the current does not pass through the MOSFET 604 (e.g., an active gate region 615 of the MOSFET 604). In contrast to the second exemplary element 500, the polysilicon region 614 does not couple the anode 610 to the MOSFET 604. Contacts 616 and a metal layer or bridge 618 may be employed to couple the eFuse 602 to the MOSFET 604 (e.g., to a gate region 615 thereof). Although the element 600 is shown in the programmed state (e.g., a high-impedance region 620 is formed in the polysilicon region 614 of the eFuse 602), the element 600 may also be configured in an unprogrammed state. The metal layer or bridge 618 may be separated from the anode 610 and gate region 620 by one or more interlevel dielectric layers. Therefore, the third exemplary element 600 may thermally isolate the MOSFET 604 during eFuse programming more than the second exemplary element 500.

The elements 100, 500, 600 described above may be damaged by radiation. For example, in response to radiation exposure, the isolation bounded elements 100, 500, 600 may exhibit increased current leakage along edges where source/drain diffusion regions and gate regions couple to the STI oxide region.

Radiation Hardened by Design (RHBD) Gain Storage Element Designs

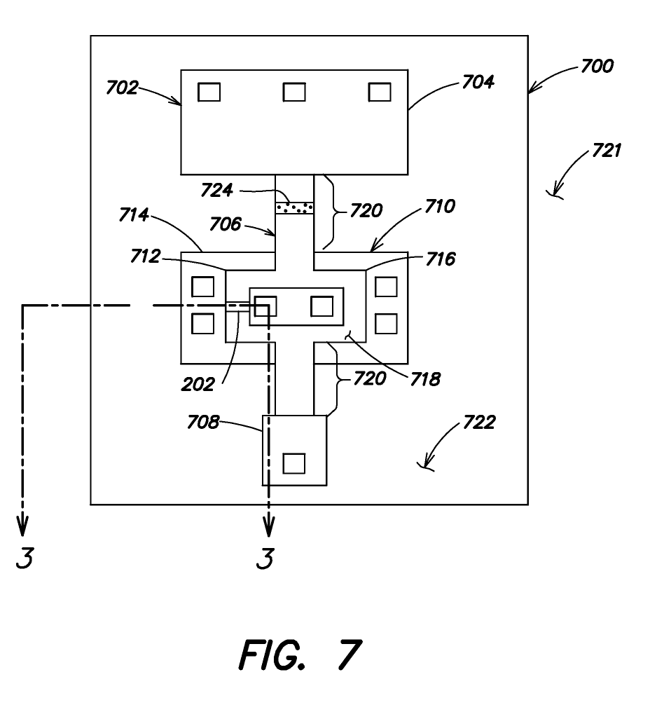

The following design structures may be adapted to reduce susceptibility of gain storage elements to radiation damage. FIG. 7 illustrates a fourth exemplary IC element 700 which includes an eFuse 702 coupled to a MOSFET in accordance with an embodiment of the present invention. With reference to FIG. 7, the fourth exemplary element 700 may be similar to the first exemplary element 100. More specifically, the fourth exemplary element 700 may include an eFuse 702 having a cathode 704 coupled via a polysilicon region 706 to an anode 708. The eFuse 702 may be programmed by driving a current through the polysilicon region 706. The element 700 may include a MOSFET 710 (e.g., an n-channel MOSFET (NFET) or a p-channel MOSFET (PFET)), which includes a gate region 712 coupled between first and second source/drain diffusion regions 714, 716, coupled to the eFuse 702. More specifically, one or more portions 718 of the polysilicon region 706 may be coupled to and/or comprise the gate region 712 (e.g., gate electrode) of the MOSFET 710. In contrast to the MOSFET 110 of the first exemplary element 100, the MOSFET 710 of the fourth exemplary element 700 may be an edgeless device. For example, the MOSFET 710 may be annular. More specifically, the gate region 712 may be annular and formed around the second source/drain diffusion region 716. Further, the first source/drain diffusion region 714 may be annular and formed around the gate region 712. Therefore, the gate region 712 of the MOSFET 710 may be bounded or enclosed by the source/drain diffusion regions 714, 716. The edgeless MOSFET 710 inherently may provide increased immunity to radiation damage (e.g., may not suffer increased current leakage due to radiation exposure). Therefore, the fourth exemplary element 700 is radiation-hardened.

A thin oxide layer (obstructed by the polysilicon region 706) may be beneath the one or more portions 718 of the polysilicon region 706 coupled to the gate region 712. Such thin oxide layer may provide MOSFET gain control. Alternatively, a thick oxide layer (obstructed by the polysilicon region 706) may be beneath remaining portions 720 of the polysilicon region 706. Such thick oxide layer may provide thermal isolation (e.g., from remaining elements of the IC 721). A shallow-trench isolation (STI) oxide region 722 may be formed adjacent the eFuse 702 and the MOSFET 710.

Although the element 700 is shown in the programmed state (e.g., a high-impedance region 724 is formed in a polysilicon region 706 of the eFuse 702), the element 700 may be fabricated in an unprogrammed state. Further, in some embodiments, the fourth exemplary element 700 may include an implanted region 202 (shown in phantom) coupling the source/drain diffusion regions 714, 716 similar to that described above with reference to FIGS. 1-3. For example, a cross-sectional side view of the fourth exemplary element 700 taken along line 3-3 in accordance with an embodiment of the present invention may be identical to that shown in FIG. 3. In an annular gain storage element, such as the fourth exemplary element 700, the implanted region 202 may be placed anywhere in the annular gate region 712 (e.g., in any one or more portions of the gate region 712). Thus, detecting an actual configuration of an IC 721 including an annular gain storage element may be more difficult than in other gain storage elements.

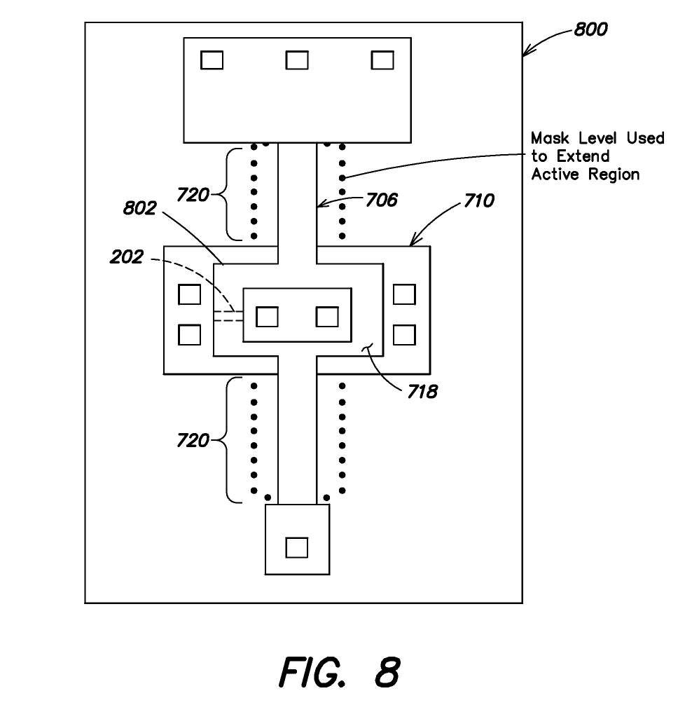

FIG. 8 illustrates a fifth exemplary IC element 800 which includes an eFuse coupled to a MOSFET in accordance with an embodiment of the present invention. With reference to FIG. 8, the fifth exemplary IC element 800 may be similar to the fourth element 700. For example, a thin oxide layer (obstructed by the polysilicon region 706) may be beneath the one or more portions 718 of the polysilicon region 706 coupled to a gate region 802. Such thin oxide layer may provide MOSFET gain control. Additionally, in contrast to the fourth element 700, a thin oxide layer (obstructed by the polysilicon region 706) may be beneath remaining portions 720 of the polysilicon region 706. Such thin oxide layer may extend an active gate region 802 of the MOSFET 710. A mask level may be employed to extend the active region. As known to one of skill in the art, such a thin oxide layer may help in reducing susceptibility to radiation damage. In this manner, the entire gain device 800 may inherently provide immunity to radiation damage. Further, although the element 800 is shown in the unprogrammed state, the element 800 may also be configured in a programmed state. In some embodiments, the fifth exemplary element 800 may include an implanted region 202 (shown in phantom) similar to that described above with reference to FIGS. 1-3.

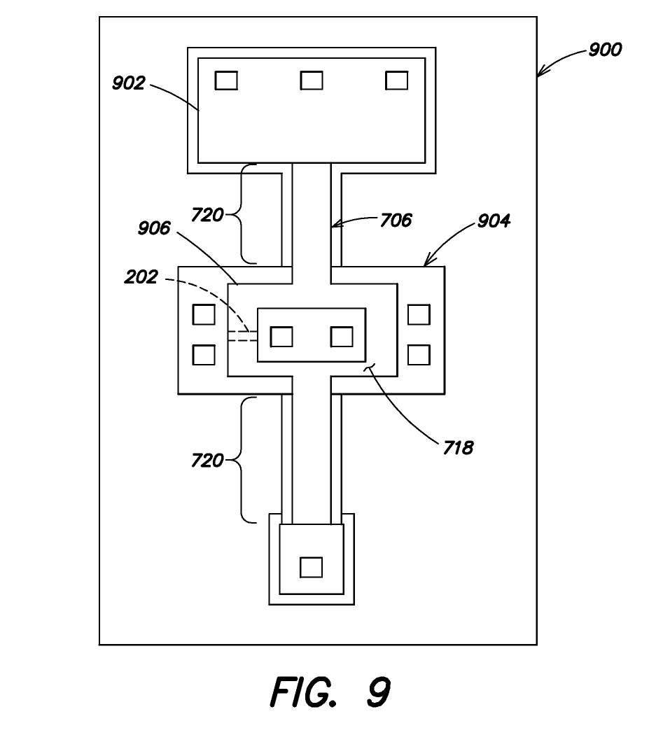

FIG. 9 illustrates a sixth exemplary IC element 900 which includes an eFuse 902 coupled to a MOSFET in accordance with an embodiment of the present invention. With reference to FIG. 9, the sixth exemplary element 900 may be similar to the fourth and fifth exemplary elements 700, 800. However, in contrast, the outer source/drain diffusion region 904 may be modified or extended to incorporate the entire programmable element (e.g., eFuse 902). Therefore, the entire element 900 including the entire programming superstructure 902 may be edgeless, thereby removing radiation susceptibility (e.g., all radiation susceptibility). A thin oxide layer (obstructed by the polysilicon region 706) may be beneath the one or more portions 718 of the polysilicon region 706 coupled to a gate region 906. Such thin oxide layer may provide MOSFET gain control. Additionally, in contrast to the fourth and fifth elements 700, 800, a thick or thin oxide layer (obstructed by the polysilicon region 706) may be beneath remaining portions 720 of the polysilicon region 706. The thickness of the oxide layer may be user-defined. The outer source/drain diffusion region 904 may enable such flexibility. Further, although the element 900 is shown in the unprogrammed state, the element 900 may also be configured in a programmed state.

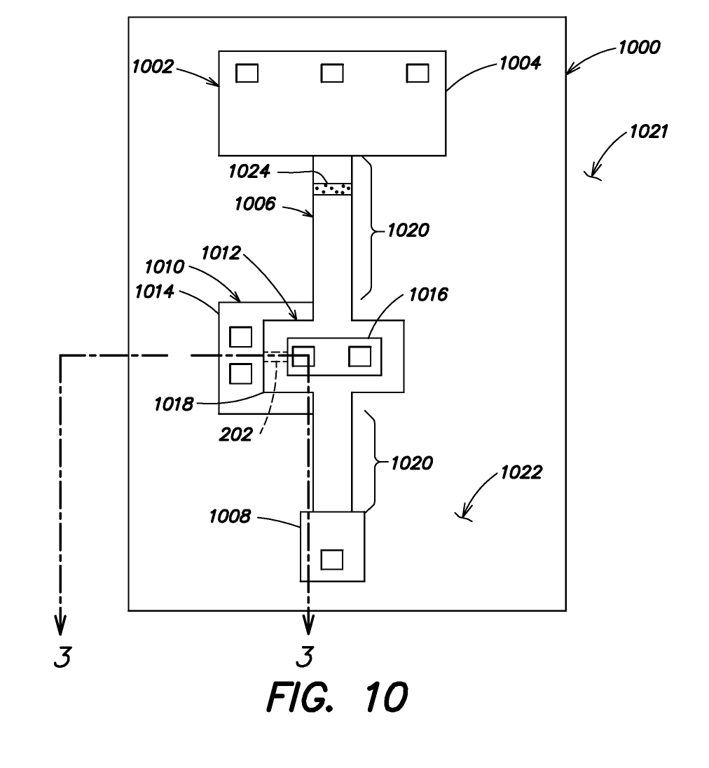

FIG. 10 illustrates a seventh exemplary IC element 1000 which includes an eFuse 1002 coupled to a MOSFET in accordance with an embodiment of the present invention. With reference to FIG. 10, the seventh exemplary element 1000 may be similar to the fourth exemplary element 700. More specifically, the seventh exemplary element 1000 may include an eFuse 1002 having a cathode 1004 coupled via a polysilicon region 1006 to an anode 1008. The eFuse 1002 may be programmed by driving a current through the polysilicon region 1006. The element 1000 may include a MOSFET 1010 (e.g., an n-channel MOSFET (NFET) or a p-channel MOSFET (PFET)), which includes a gate region 1012 coupled between first and second source/drain diffusion regions 1014, 1016, coupled to the eFuse 1002. More specifically, one or more portions 1018 of the polysilicon region 1006 may be coupled to and/or comprise the gate region 1012 (e.g., gate electrode) of the MOSFET 1010. In contrast, the annular MOSFET 710 of the fourth exemplary element 700, the first diffusion region 1014 is not annular. However, the first diffusion region 1014 may enclose the gate region 1012 such that the MOSFET 1010 is edgeless. Such an edgeless MOSFET 1010 inherently may provide increased immunity to radiation damage (e.g., may not suffer increased current leakage due to radiation exposure). For example, such a design may reduce or eliminate edge susceptibility. Therefore, the seventh exemplary element 1000 is radiation-hardened. Further, compared with the exemplary elements 700, 900 including a full annular MOSFET 710, 904, the seventh exemplary element 1000 may provide a reduced gain cell Miller capacitance (e.g., a capacitance between the enclosed gate region 1012 and first source/drain diffusion region 1014) and a reduced junction capacitance (e.g., a capacitance related to the area of the first source/drain diffusion region 1014).

A thin oxide layer (obstructed by the polysilicon region 1006) may be beneath the one or more portions 1018 of the polysilicon region 1006 coupled to and/or comprising the gate region 1012. Such thin oxide layer may provide MOSFET gain control. Additionally, a thick oxide layer (obstructed by the polysilicon region 1006) may be beneath remaining portions 1020 of the polysilicon region 1006. Such thick oxide layer may provide thermal isolation (e.g., from remaining elements of the IC 1021). A shallow-trench isolation (STI) oxide region 1022 may be formed adjacent the eFuse 1002 and the MOSFET 1010.

Although the element 1000 is shown in the programmed state (e.g., a high-impedance region 1024 is formed in a polysilicon region 1006 of the eFuse 1002), the element 1000 may also be configured in an unprogrammed state. Further, in some embodiments, the seventh exemplary element 1000 may include an implanted region 202 (shown in phantom) coupling the source/drain diffusion regions 1014, 1016 similar to that described above with reference to FIGS. 1-3. For example, a cross-sectional side view of the seventh exemplary element 1000 taken along line 3-3 in accordance with an embodiment of the present invention may be identical to that shown in FIG. 3.

In an enclosed-gate region gain storage element, such as the seventh exemplary element 700, the implanted region 202 may be placed anywhere in the enclosed gate region 1012 (e.g., in any one or more portions of the enclosed gate region 1012). Thus, detecting an actual configuration of an IC 1021 including an enclosed-gate gain storage element may be more difficult than in other gain storage elements.

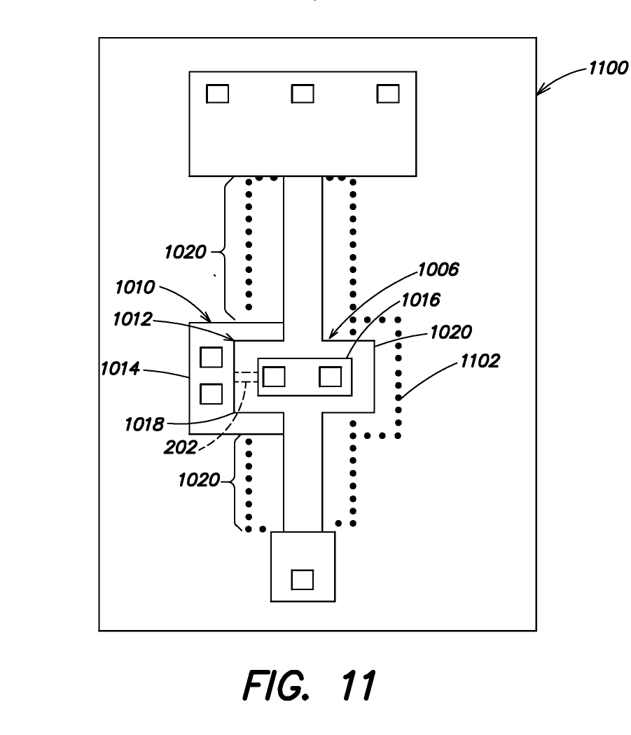

FIG. 11 illustrates an eighth exemplary IC element 1100 which includes an eFuse coupled to a MOSFET in accordance with an embodiment of the present invention. With reference to FIG. 11, the eighth exemplary element 1100 may be similar to the seventh exemplary element 1000. For example, a thin oxide layer (obstructed by the polysilicon region 1006) may be beneath the one or more portions 1018 of the polysilicon region 1006 coupled to the gate region 1012. Such thin oxide layer may provide MOSFET gain control. Additionally, in contrast to the seventh exemplary element 1000, a thin oxide layer (obstructed by the polysilicon region 1006) may be beneath remaining portions 1020 of the polysilicon region 1006. Such thin oxide layer may extend an active gate region 1012 of the MOSFET 1010. A mask level 1102 may be employed to extend the active region. As known to one of skill in the art, such a thin oxide layer may help in reducing susceptibility to radiation damage. In this manner, the entire gain device 1100 may inherently provide immunity to radiation damage. Further, although the element 1100 is shown in the unprogrammed state, the element 1100 may also be configured in a programmed state. Additionally, in some embodiments, similar to the seventh exemplary element 1000, the eighth exemplary element 1100 may include an implanted region 202 (shown in phantom) coupling the source/drain diffusion regions 1014, 1016.

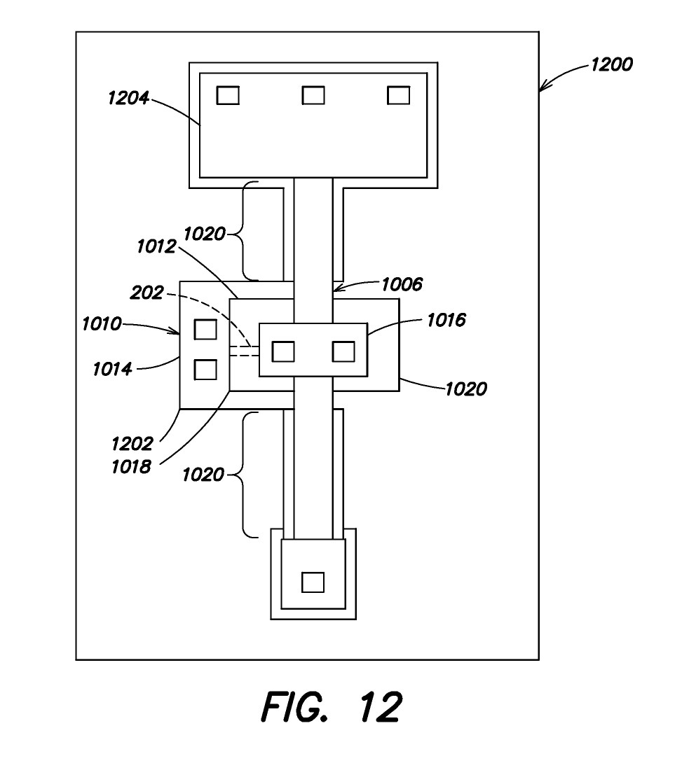

FIG. 12 illustrates a ninth exemplary IC element 1200 which includes an eFuse coupled to a MOSFET in accordance with an embodiment of the present invention. With reference to FIG. 12, the ninth exemplary element 1200 may be similar to the seventh and eighth exemplary elements 1000, 1100. However, in contrast, the outer (e.g., first) source/drain diffusion region 1202 may be modified or extended to incorporate most or the entire programmable element (e.g., eFuse 1204). Therefore, a majority of the entire element 1200 may be edgeless, thereby removing radiation susceptibility. A thin oxide layer (obstructed by the polysilicon region 1006) may be beneath the one or more portions 1018 of the polysilicon region 1006 coupled to the gate region 1012. Such thin oxide layer may provide MOSFET gain control. Additionally, in contrast to the seventh and eighth elements 1000, 1100, a thick or thin oxide layer (obstructed by the polysilicon region 1006) may be beneath remaining portions 1020 of the polysilicon region 1006. The thickness of the oxide layer may be user-defined. The outer source/drain diffusion region 1202 may enable such flexibility.

Additionally, similar to the seventh exemplary element 1000, some embodiments at the ninth exemplary element 1200 may include an implanted region 202 (shown in phantom) coupling the source/drain diffusion regions 1202, 1016. Further, although the element 1200 is shown in the unprogrammed state, the element 1200 may also be configured in a programmed state.

The MOSFETs 710, 1010 of the fourth through ninth exemplary elements 700-1200 are in a programming path of an eFuse coupled thereto. Therefore, such MOSFETs may be affected by thermal energy created during eFuse programming.

Radiation-Hardened Thermally-Isolating Designs

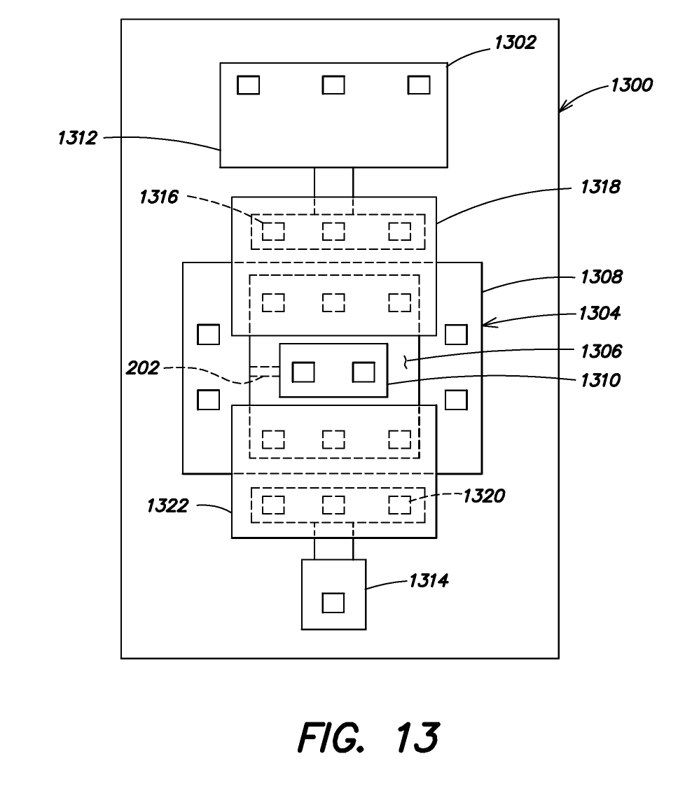

The following design structures may be adapted to reduce susceptibility of gain storage elements to radiation damage while providing thermal isolation to the gain cell (e.g., MOSFET) while programming a programmable cell (e.g., eFuse) of the gain storage element. Such structures may be useful in sub-45 nm structures to reduce or eliminate thermal damage. FIG. 13 illustrates a tenth exemplary IC element 1300 which includes an eFuse coupled to a MOSFET in accordance with an embodiment of the present invention. With reference to FIG. 13, the tenth exemplary element 1300 may include an eFuse 1302 coupled to a MOSFET 1304 (e.g., an n-channel MOSFET (NFET) or a p-channel MOSFET (PFET)), which includes a gate region 1306 coupled between first and second source/drain diffusion regions 1308, 1310. The MOSFET 1304 of the tenth exemplary element 1300 may be a 100% edgeless device. For example, the MOSFET 1304 may be fully annular. More specifically, the gate region 1306 may be fully annular and formed around the second source/drain diffusion region 1310. Further, the first source/drain diffusion region 1308 may be fully annular and formed around the gate region 1306. Therefore, the gate region 1306 may be bounded or enclosed by the source/drain diffusion regions 1308, 1310. The 100% edgeless MOSFET 1304 inherently may provide increased immunity (e.g., total immunity) to radiation damage (e.g., may not suffer increased current leakage due to radiation exposure). For example, the MOSFET 1304 (e.g., gain element) may provide total immunity to such radiation because the gain element may not have any polysilicon regions or line which cross an active area thereof. Therefore, the tenth exemplary element 1300 is radiation-hardened.

To couple the eFuse 1302 to the 100% edgeless MOSFET 1304, the eFuse 1302 may be separated into a plurality of portions. For example, a first portion 1312 of the eFuse 1302 may serve as a cathode and a second portion 1314 of the eFuse 1302 may serve as an anode. A first set of contacts 1316 and a first metal layer or bridge 1318 may be employed to couple the cathode 1312 to an active region of the MOSFET 1304 (e.g., the gate region 1306). A second set of contacts 1320 and a second metal layer or bridge 1322 may be employed to couple the anode 1314 to the gate region 1306. Therefore, the eFuse 1302 may be interrupted by the MOSFET 1304. Although the gate region 1306 of the MOSFET 1304 is in a programming path of the eFuse 1302, the jumpers (e.g., first and second metal layers or bridges 1318, 1322) coupling the cathode 1312 to the gate region 1306 and coupling the anode 1314 to the gate region 1306 may provide some thermal isolation to the gate region 1306 during eFuse programming. Further, in some embodiments, the tenth exemplary element 1300 may include an implanted region 202 (shown in phantom) similar to that described above with reference to FIG. 8. Additionally, although the element 1300 is shown in the unprogrammed state, the element 1300 may also be configured in a programmed state.

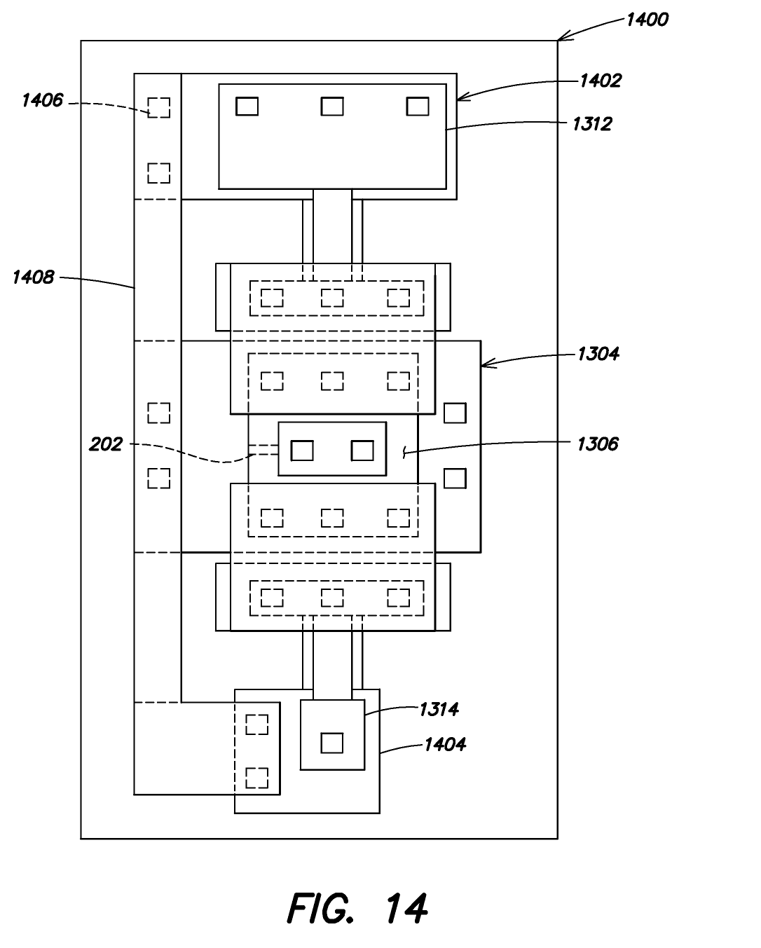

FIG. 14 illustrates an eleventh exemplary IC element 1400 which includes an eFuse coupled to a MOSFET in accordance with an embodiment of the present invention. With reference to FIG. 14, the eleventh exemplary element 1400 may be similar to the tenth exemplary element 1300. Similar to the fully annular first source/drain diffusion region 1308, annular diffusion regions 1402, 1404 may be formed around the cathode 1312 and anode 1314, respectively. Therefore, the cathode 1312, anode 1314 and MOSFET 1304 (e.g., the entire gain storage element 1400) may not have any polysilicon lines crossing an active area. Further, the outer diffusion regions 1402, 1404, 1304 around the cathode 1312, anode 1314 and gate region 1306 are not isolation-bounded. Additionally, contacts 1406 and metal layers or bridges 1408 may be employed to couple the outer diffusion regions 1402, 1404, 1304. Thus, the entire gain storage element may inherently provide immunity (e.g., total immunity). The metal layers or bridges 1408 may couple such diffusion regions 1402, 1404, 1304 to a fixed potential (e.g. so such regions do not float). Consequently, the eleventh exemplary element 1400 is radiation-hardened. Although the element 1400 is shown in the unprogrammed state, the element 1400 may also be configured in a programmed state. Further, in some embodiments, the eleventh exemplary element 1400 may include an implanted region 202 (shown in phantom) similar to that described above with reference to FIG. 8.

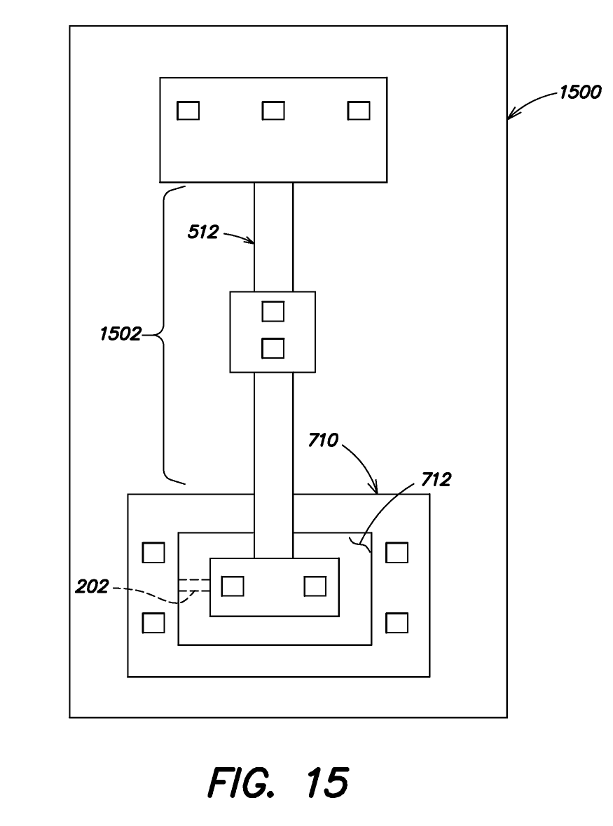

FIG. 15 illustrates a twelfth exemplary IC element which includes an eFuse coupled to a MOSFET in accordance with an embodiment of the present invention. With reference to FIG. 15, the twelfth exemplary element 1500 may provide thermal isolation in a manner similar to the second exemplary element 500. However, in contrast, the twelfth exemplary IC element 1500 includes the annular MOSFET 710 of the fourth exemplary element 700. A thick oxide layer may be formed beneath a portion 1502 of the polysilicon region 512. Such thick oxide layer may provide thermal isolation. The twelfth exemplary element 1500 may provide an inline annular element including a programming path of a programmable cell that is thermally isolated from the gain cell 710. However, because the polysilicon region 512 may be on the same level as the gate region 712 of the MOSFET 710, some thermal energy may reach the gate region 712 while programming the element 1500.

Further, in some embodiments, the twelfth exemplary element 1500 may include an implanted region 202 (shown in phantom) similar to that described above with reference to FIGS. 1-3. Additionally, although the element 1500 is shown in the unprogrammed state, the element 1500 may also be configured in a programmed state.

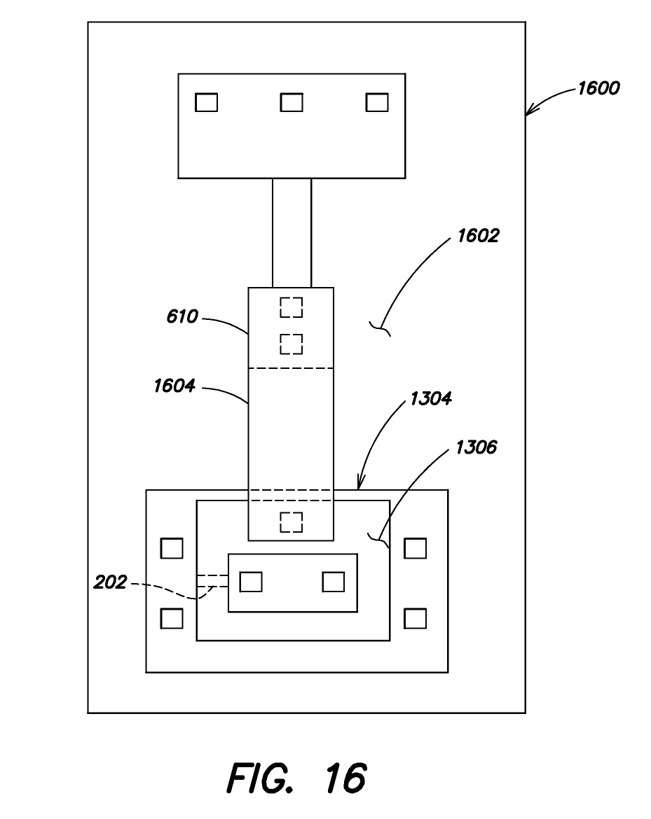

FIG. 16 illustrates a thirteenth exemplary IC element 1600 which includes an eFuse coupled to a MOSFET in accordance with an embodiment of the present invention. With reference to FIG. 16, the thirteenth exemplary element 1600 may provide thermal isolation in a manner similar to the third exemplary element 600. However, in contrast, the thirteenth exemplary element 1600 includes the 100% edgeless fully annular MOSFET 1304 of the tenth exemplary element 1300. In this manner, the thirteenth exemplary element 1600 may provide an inline annular element including a programming path of a programmable cell that is thermally isolated from the gain cell. The gate region 1306 of the fully annular MOSFET 1304 may not abut an STI oxide region 1602, thereby reducing or eliminating edge leakage related to radiation. A metal layer or bridge 1604 employed to couple the anode 610 and gate region 1306 may be separated from the anode 610 and gate region 1306 by one or more interlevel dielectric layers. Therefore, the thirteenth exemplary element 1600 may thermally isolate the MOSFET 1304 during eFuse programming more than the twelfth exemplary element 1500. Further, in some embodiments, the thirteenth exemplary element 1600 may include an implanted region 202 (shown in phantom) similar to that described above with reference to FIGS. 1-3. Additionally, although the element 1600 is shown in the unprogrammed state, the element 1600 may also be configured in a programmed state.

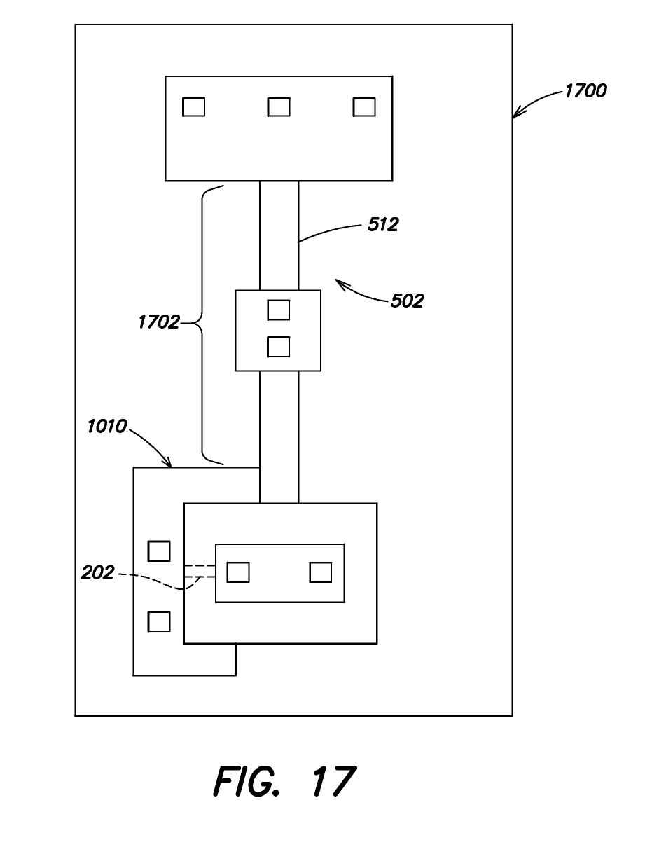

FIG. 17 illustrates a fourteenth exemplary IC element 1700 which includes an eFuse coupled to a MOSFET in accordance with an embodiment of the present invention. With reference to FIG. 17, the fourteenth exemplary element 1700 may provide thermal isolation in a manner similar to the second exemplary element 500. However, in contrast, the fourteenth exemplary IC element 1700 includes the enclosed-gate MOSFET 1010 of the seventh exemplary element 1000. A thick oxide layer (obstructed by polysilicon layer 512) may be formed beneath a portion 1702 of the polysilicon region 512. Such thick oxide layer may provide thermal isolation. In this manner, the fourteenth exemplary element 1700 may provide a gain cell which is edgeless and which is thermally isolated from a programming current path of the eFuse 502. Further, in some embodiments, the fourteenth exemplary element 1700 may include an implanted region 202 (shown in phantom) similar to that described above with reference to FIGS. 1-3. Additionally, although the element 1700 is shown in the unprogrammed state, the element 1700 may also be configured in a programmed state.

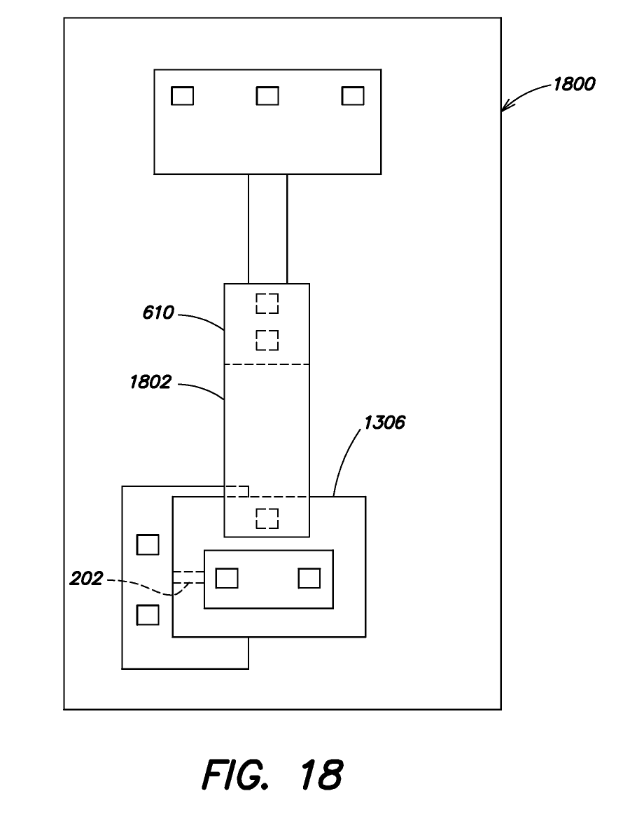

FIG. 18 illustrates a fifteenth exemplary IC element 1800 which includes an eFuse coupled to a MOSFET in accordance with an embodiment of the present invention. With reference to FIG. 18, the fifteenth exemplary element 1800 may provide thermal isolation in a manner similar to the third exemplary element 600. However, in contrast, the fifteenth exemplary element 1800 includes the enclosed-gate MOSFET 1010 of the seventh exemplary element 1000. In this manner, the fifteenth exemplary element 1800 may provide an inline annular element including a programming path of a programmable cell that is thermally isolated from the gain cell. A metal layer or bridge 1802 employed to couple the anode 610 and gate region 1306 may be separated from the anode 610 and gate region 1306 by one or more interlevel dielectric layers. Therefore, the fifteenth exemplary element 1800 may thermally isolate the MOSFET 1306 during eFuse programming more than the fourteenth exemplary element 1700. Further, in some embodiments, the fifteenth exemplary element 1800 may include an implanted region 202 (shown in phantom) similar to that described above with reference to FIGS. 1-3. Additionally, although the element 1800 is shown in the unprogrammed state, the element 1800 may also be configured in a programmed state.

As described above, the present invention provides an exemplary amplifying digital gain storage element 100, 500, 600, 700, 800, 900, 1000, 1100, 1200, 1300, 1400, 1500, 1600 1700, 1800, 1900 including a separate programming and gain-sensing path of the element and methods of using the same. The exemplary element may be adapted to provide a first gain when programmed and a second gain when unprogrammed. Further, a difference between gain provided by such an exemplary element when programmed and unprogrammed may be about eight orders of magnitude. Consequently, a chance of the gain provided by the element being incorrectly sensed (e.g., read) is small. Additionally, in some embodiments, an exemplary element may include an implanted region 202 adapted to cause the element (e.g., MOSFET included therein) to provide a fixed gain regardless of a programmed state of the element. The programmed state of the element may be easily detected. However, the implanted region may be hidden (e.g., buried below other components of the element), and therefore, may be difficult to detect. Consequently, the programmed state of the element may serve a decoy for the actual IC configuration, thereby disguising such configuration.

The present invention may overcome problems with conventional IC elements, thereby providing an improved storage element (e.g., permanent storage element) for personalizing, repairing or altering a semiconductor component or an IC. By employing an eFuse rather than a laser fuse (minimum size of which is limited by equipment) in the IC, a chip area required by the element may be reduced. Further, the eFuse may enable in-situ box customization.

Further, analog resistances provided by programmed eFuses may fluctuate. Such fluctuation may adversely affect an ability to detect a change in state of such programmed eFuses. By decoupling the sensing path from the programming path, the element of the present invention avoids such problem.

Additionally, some conventional circuitry employed to sense a state of a storage element may be adversely affected by high-energy electromagnetic radiation, such as that encountered in outer space or a military environment (e.g., x-rays, gamma-rays and/or the like). For example, such circuitry may be exhibit a large degradation in an off-state leakage current. In contrast, some embodiments of the present invention may be insensitive to a high-radiation environment.

By combining an eFuse and MOSFET in the manner described above, the present invention may reduce sensing errors by improving upon the element being sensed as opposed to adding complex analog sense circuitry. For example, the element may be insensitive to programming variations described above. Additionally, the semiconductor element has an intrinsic gain delta between programmed and unprogrammed states. For example, in the programmed state, a portion of the eFuse that may serve as a gate electrode (e.g., cathode) may be isolated from the MOSFET by placing the input path in a high impedance state. This intrinsic gain should manifest itself in a many order of magnitude gain change between the states. Such a gain is decoupled from the physical programming since sensing is determined by a current flow through the amplifying device (e.g., MOSFET) as opposed to current between the anode and cathode terminals of the eFuse alone. Due to such decoupling, the final amplifying program element may be insensitive to self-healing. Further, this decoupling provides an element with a gain difference between a programmed and an unprogrammed state of the element. As stated, the gain difference may be substantial such that either state is easily identified, thereby removing a dependency on additional circuitry such as an analog sense latch.

In summary, a MOSFET may be coupled in series with a polysilicon conductor (e.g., eFuse). In some embodiments, a portion of the MOSFET and the eFuse may be the same physically connected conductor. In some embodiments, the conductor path is actually interrupted and reconnected on a subsequent upper level of metal.

The foregoing description discloses only exemplary embodiments of the invention. Modifications of the above disclosed apparatus and methods which fall within the scope of the invention will be readily apparent to those of ordinary skill in the art. For instance, it should be noted that the MOSFET of any exemplary element may be an NFET, PFET or another suitable type of transistor. Additionally, the exemplary element may be formed on a bulk substrate, silicon-on-insulator substrate or another suitable substrate. Further, although each IC is described above as including only one exemplary gain storage element, an IC may include a plurality of such exemplary elements which may enable/disable respective functions of the IC. The collective functional state of the plurality of exemplary elements may serve to identify a configuration of the IC, thereby serving as “digital DNA” of the IC. If one or more of the exemplary elements includes an implanted region 202, the collective programmed state of the elements may serve as a decoy for the actual functional state of the elements. These new decoying elements can be inserted into the digital DNA of any string (e.g., of elements). Programming of such elements may be randomized making reverse engineering and/or defeating a programmed IC state by physical means impossible regardless of an number of chips compared. In this manner, certain applications or features of the IC may be disabled to provide security and prevent unauthorized use while preventing reverse engineering or chip modification by opening up an IC package, delayering, and using means such as focused ion beams (FIB).

Additionally, similar to the first exemplary element 100, each of the second through fifteenth exemplary elements 500, 600, 700, 800, 900, 1000, 1100, 1200, 1300, 1400, 1500, 1600 1700, 1800, 1900 may include a silicide layer 304. However, for convenience, such silicide layer is not shown in FIGS. 5-18. Further, an individual exemplary element may be programmed with either high power or low power, thus allowing for either internal or external programming methodologies. Employing low power to program the element using internal levels may provide advantages over conventional systems.

Accordingly, while the present invention has been disclosed in connection with exemplary embodiments thereof, it should be understood that other embodiments may fall within the spirit and scope of the invention, as defined by the following claims.

The invention claimed is:

1. An element of an integrated circuit (IC), comprising:
a metal-oxide-semiconductor field-effect transistor (MOSFET) having source/drain diffusion regions;
an electrical fuse (eFuse) coupled to the MOSFET such that a portion of the eFuse serves as a gate region of the MOSFET; and
an implanted region coupled to the source/drain diffusion regions of the MOSFET such that a path between the source/drain diffusion regions functions as a short circuit or an open circuit.

2. The element of claim 1 wherein:
the MOSFET is an n-channel MOSFET;
the implanted region includes n-type dopant with a concentration of about 4×10¹⁷ to about 1×10¹⁸ ions/cm³; and
the implanted region is coupled to the source/drain diffusion regions of the MOSFET such that the path between the source/drain diffusion regions functions as a short circuit.

3. The element of claim 1 wherein:
the MOSFET is an n-channel MOSFET;
the implanted region includes p-type dopant with a concentration of greater than about 1×10¹⁸ ions/cm³; and
the implanted region is coupled to the source/drain diffusion regions of the MOSFET such that the path between the source/drain diffusion regions functions as an open circuit.

4. The element of claim 1 wherein:
the MOSFET is a p-channel MOSFET;
the implanted region includes p-type dopant with a concentration of about 4×10¹⁷ to about 1×10¹⁸ ions/cm³; and
the implanted region is coupled to the source/drain diffusion regions of the MOSFET such that the path between the source/drain diffusion regions functions as a short circuit.

5. The element of claim 1 wherein:
the MOSFET is a p-channel MOSFET;
the implanted region includes n-type dopant with a concentration of greater than about 1×10¹⁸ ions/cm³; and
the implanted region is coupled to the source/drain diffusion regions of the MOSFET such that the path between the source/drain diffusion regions functions as an open circuit.

6. The element of claim 1 wherein the implanted region is formed in one or more portions of the gate region such that the path between the source/drain diffusion regions via the implanted region functions as a short circuit.

7. The element of claim 1 wherein the implanted region is formed in one or more portions of the gate region such that the path between the source/drain diffusion regions via the implanted region functions as an open circuit.

8. The element of claim 1 wherein the element is adapted to provide at least one of radiation resistance and thermal isolation.

9. The element of claim 1 wherein a current gain provided by the MOSFET is based on the implanted region and is independent of a programmed state of the eFuse.

10. An integrated circuit (IC), comprising:
a substrate; and
an element formed on the substrate, the element including:
a metal-oxide-semiconductor field-effect transistor (MOSFET) having source/drain diffusion regions;
an electrical fuse (eFuse) coupled to the MOSFET such that a portion of the eFuse serves as a gate region of the MOSFET; and
an implanted region coupled to the source/drain diffusion regions of the MOSFET such that a path between the source/drain diffusion regions functions as a short circuit or an open circuit.

11. The IC of claim 10 wherein:
the MOSFET is an n-channel MOSFET;
the implanted region includes n-type dopant with a concentration of about 4×10¹⁷ to about 1×10¹⁸ ions/cm³; and
the implanted region is coupled to the source/drain diffusion regions of the MOSFET such that the path between the source/drain diffusion regions functions as a short circuit.

12. The IC of claim 10 wherein:
the MOSFET is an n-channel MOSFET;
the implanted region includes p-type dopant with a concentration of greater than about 1×10¹⁸ ions/cm³; and
the implanted region is coupled to the source/drain diffusion regions of the MOSFET such that the path between the source/drain diffusion regions functions as an open circuit.

13. The IC of claim 10 wherein:
the MOSFET is a p-channel MOSFET;
the implanted region includes p-type dopant with a concentration of about 4×10¹⁷ to about 1×10¹⁸ ions/cm³; and
the implanted region is coupled to the source/drain diffusion regions of the MOSFET such that the path between the source/drain diffusion regions functions as a short circuit.

14. The IC of claim 10 wherein:
the MOSFET is a p-channel MOSFET;
the implanted region includes n-type dopant with a concentration of greater than about 1×10¹⁸ ions/cm³; and
the implanted region is coupled to the source/drain diffusion regions of the MOSFET such that the path between the source/drain diffusion regions functions as an open circuit.

15. The IC of claim 10 wherein the implanted region is formed in one or more portions of the gate region such that the path between the source/drain diffusion regions via the implanted region functions as a short circuit.

16. The IC of claim 10 wherein the implanted region is formed in one or more portions of the gate region such that the path between the source/drain diffusion regions via the implanted region functions as an open circuit.

17. The IC of claim 10 wherein the element is adapted to provide at least one of radiation resistance and thermal isolation.

18. The IC of claim 10 wherein a current gain provided by the MOSFET is based on the implanted region and is independent of a programmed state of the eFuse.

19. A method, comprising:
providing an element of an integrated circuit (IC), comprising:
a metal-oxide-semiconductor field-effect transistor (MOSFET) having source/drain diffusion regions;
an electrical fuse (eFuse) coupled to the MOSFET such that a portion of the eFuse serves as a gate region of the MOSFET; and
an implanted region coupled to the source/drain diffusion regions of the MOSFET such that a path between the source/drain diffusion regions functions as a short circuit or an open circuit; and
employing the element to provide a current gain independent of a programmed state of the eFuse.

20. The method of claim 19 further comprising providing radiation resistance while employing the element to provide a current gain independent of the programmed state of the eFuse.

21. The method of claim 19 further comprising providing thermal isolation while employing the element to provide a current gain independent of the programmed state of the eFuse.

22. The method of claim 19 further comprising employing a programmed state of the eFuse to disguise configuration of the IC.
